(19) United States
(12) Patent Application Publication
(10) Pub. No.: US 2026/0189194 A1
(43) Pub. Date: Jul. 2, 2026

(54) AMPLIFICATION CIRCUIT FOR OPERATION IN MULTIPLE GAIN MODES

(71) Applicant: RichWave Technology Corp., Taipei City (TW)

(72) Inventors: Chia-Wei Hsu, Taipei City (TW); Yen-Hsun Lu, Taipei City (TW)

(73) Assignee: RichWave Technology Corp., Taipei City (TW)

(21) Appl. No.: 19/096,626

(22) Filed: Mar. 31, 2025

(30) Foreign Application Priority Data
Jan. 2, 2025 (TW) 114100068

(51) Int. Cl. H03F 1/32; H03F 1/56

(52) U.S. Cl. CPC H03F 1/3205; H03F 1/56; H03F 2200/222; H03F 2200/387; H03F 2200/451

(57) ABSTRACT

An amplification circuit includes a signal input terminal, a signal output terminal, a first transistor, a variable impedance element, and a voltage adjustment circuit. The signal input terminal receives a radio frequency signal, and the signal output terminal outputs an amplified radio frequency signal. The first transistor has a first terminal coupled to a reference voltage terminal and a control terminal coupled to the signal input terminal. The variable impedance element is coupled between the first transistor and the signal output terminal and includes a second transistor. A first terminal of the second transistor is coupled to the first transistor, the second terminal of the second transistor is coupled to the signal output terminal, and the control terminal of the second transistor receives a bias signal. The voltage adjustment circuit is coupled to the variable impedance element to adjust the voltage at the second terminal of the second transistor.

### TECHNICAL FIELD

The invention is related to an amplification circuit, and specifically, to a multi-gain amplification circuit for operation in multiple gain modes.

### BACKGROUND

Amplification circuits are widely used in various electronic circuits, such as radio frequency (RF) circuits. In some applications, multi-gain amplification circuits may selectively operate in at least one gain mode, such as a high-gain mode or a low-gain mode, to achieve different levels of amplification for RF signals. The linearity of the amplification circuit in different gain modes is one of the key factors in technical considerations.

### SUMMARY

According to an embodiment of the invention, an amplification circuit includes a signal input terminal, a signal output terminal, a first transistor, a variable impedance element, and a voltage adjustment circuit. The signal input terminal is used to receive a radio frequency (RF) signal. The signal output terminal is used to output an amplified RF signal. The first transistor has a first terminal coupled to a reference voltage terminal and a control terminal coupled to the signal input terminal. The variable impedance element is coupled between the first transistor and the signal output terminal. The variable impedance element includes a second transistor, wherein a first terminal of the second transistor is coupled to the second terminal of the first transistor, a second terminal of the second transistor is coupled to the signal output terminal, and a control terminal of the second transistor is used to receive a first bias signal. The voltage adjustment circuit is coupled to the variable impedance element and is used to adjust a voltage at the second terminal of the second transistor.

The amplification circuit according to at least one embodiment of the present invention may provide improved linearity in multiple gain modes. In order to make the above features and advantages of the present invention more clearly understood, embodiments are given below and described in detail with reference to the accompanying drawings.

### BRIEF DESCRIPTION OF THE DRAWINGS

FIGS. 1 to 5 are schematic diagrams of amplification circuits according to various embodiments of the invention.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

The present invention can be understood by referring to the following detailed description in conjunction with the accompanying drawings. It should be noted that, for ease of understanding and to maintain the simplicity of the drawings, only a portion of the electronic device is illustrated in the figures. Additionally, specific elements in the drawings are not drawn to actual scale. The quantity and dimensions of elements shown in the figures are merely illustrative and are not intended to limit the scope of the invention. Elements indicated by the same reference symbols in the figures possess the same or similar attributes or functions throughout the description.

It should be understood that the features of the embodiments provided below can be interchanged, reorganized, or combined across different embodiments to create other implementations without departing from the spirit of the invention. As long as the features of each embodiment align with the spirit of the invention, the embodiments can be used individually or in combination.

In this specification, when an element is described as being “coupled” to another element, it may refer to a direct connection or an indirect connection via other elements. The term “reference voltage terminal” as used herein can refer to a substantially stable reference voltage. The reference voltage terminal may include, but is not limited to, a ground terminal. Multiple reference voltage terminals mentioned herein can refer to either the same reference voltage terminal or different reference voltage terminals.

When an element is described as being “optionally provided” or “selectively provided,” it means the element may be included or omitted depending on the requirements, and both scenarios fall within the scope of the embodiments.

In the following description and claims, terms such as “comprising,” “including,”

and “having” are open-ended terms and should be interpreted as “including but not limited to.” Therefore, when terms such as “comprising,” “including,” and/or “having” are used in the description of the present invention, they specify the presence of corresponding features, regions, steps, operations, and/or components but do not exclude the presence of one or more additional features, regions, steps, operations, and/or components.

In the specification, when referred to transistors, it may include a P-type transistor and an N-type transistor. For instance, in the case of a field-effect transistor (FET), the first terminal of the transistor may correspond to either the drain or the source, the second terminal may correspond to the other, and the control terminal may correspond to the gate. In the case of a bipolar junction transistor (BJT), the first terminal of the transistor may correspond to either the collector or the emitter, the second terminal may correspond to the other, and the control terminal may correspond to the base.

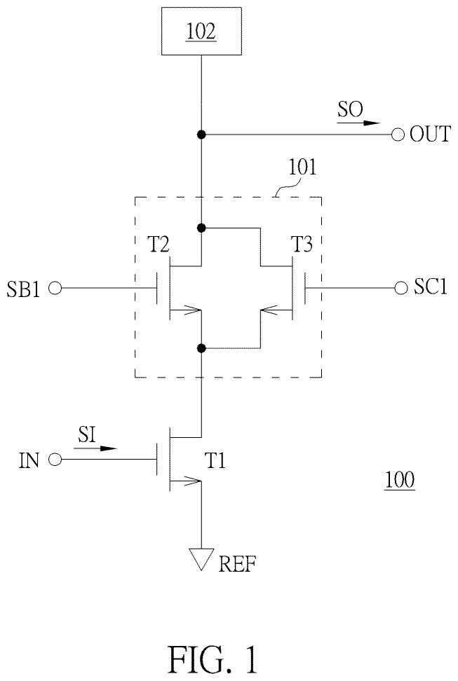

FIG. 1 illustrates a schematic diagram of an amplification circuit 100 according to an embodiment of the present invention. In FIG. 1, the amplification circuit 100 may include a signal input terminal IN, a signal output terminal OUT, a first transistor T1, a variable impedance element 101, and a voltage adjustment circuit 102. Specifically, the signal input terminal IN may be used to receive a radio frequency (RF) signal SI, and the signal output terminal OUT may output the amplified RF signal SO after amplification. The first terminal (e.g., source) of the first transistor T1 may be coupled to a reference voltage terminal REF, and the control terminal (e.g., gate) may be coupled to the signal input terminal IN. In some embodiments, the actual level of the reference voltage terminal REF may be determined based on the design. For example, the reference voltage terminal REF may provide a ground voltage or other fixed voltages. The variable impedance element 101 may be coupled between the first transistor T1 and the signal output terminal OUT, where the variable impedance element 101 may include a second transistor T2. The first terminal (e.g., source) of the second transistor T2 may be coupled to the second terminal of the first transistor T1, the second terminal (e.g., drain) of the second transistor T2 may be coupled to the signal output terminal OUT, and the control terminal (e.g., gate) of the second transistor T2 may be configured to receive a first bias signal SB1. The voltage adjustment circuit 102 may be coupled to the variable impedance element 101 and configured to adjust the voltage at the second terminal of the second transistor T2.

In the above embodiment, the second transistor T2 may be configured in a cascode arrangement with the first transistor T1. In some embodiments, the first transistor T1 may be referred to as a common-source transistor or a common-emitter transistor, while the second transistor T2 may be referred to as a common-gate transistor or a common-base transistor. However, the invention is not limited to this specific arrangement, and in other embodiments, transistors T1 to T2 may also be implemented using other suitable electronic devices. In further embodiments, the amplification circuit 100 may include additional transistors stacked with either the first transistor T1 or the second transistor T2. For instance, additional transistors may be stacked between the first transistor T1 and the second transistor T2. In some embodiments, the control terminal of the first transistor T1 may also receive the first bias signal SB1. Alternatively, the control terminal of the first transistor T1 may receive a second bias signal SB2 (not shown) different from the first bias signal SB1.

As shown in FIG. 1, the variable impedance element 101 may further include a third transistor T3. The first terminal (e.g., source) of the third transistor T3 may be coupled to the first terminal of the second transistor T2, the second terminal (e.g., drain) of the third transistor T3 may be coupled to the second terminal of the second transistor T2, and the control terminal of the third transistor T3 may be configured to receive a first control signal SC1. As shown in FIG. 1, the second transistor T2 may, for example, be implemented as an N-type transistor, and the third transistor T3 may also be implemented as an N-type transistor.

In some embodiments, the transistors T1 to T3 may be fabricated using a Silicon-On-Insulator (SOI) process. Furthermore, the first transistor T1 may include a body (or bulk) terminal, and the body terminal may, for example, be floating. The second transistor T2 may include a body terminal that may be either contact-connected (also referred to as tie-connected, or tied) or be floating. The third transistor T3 may include a body terminal which may be contact-connected.

A floating body terminal may mean that the body terminal is not related to a predetermined voltage, while a contact-connected body terminal may mean that the body terminal is coupled to a predetermined voltage terminal to maintain at a predetermined voltage level.

For example, a transistor having a floating body terminal may offer a lower noise figure (NF). However, due to the potentially unstable voltage at the floating body terminal, the transistor may take an undesirable period to complete a state transition. For instance, when the operating state of the amplification circuit 100 transitions, a transistor having a floating body terminal may need more time to reach a steady state, leading to less favorable transient response characteristics. In comparison, a transistor having a contact-connected body terminal may present better transient response by reaching the steady state more quickly, though the noise figure may be increased. For example, in one embodiment, the body terminal of the first transistor T1 and that of the second transistor T2 may be floating, while the body terminal of the third transistor T3 may be contact-connected. Such configuration may balance the amplifier's noise figure and transient response characteristics.

In some embodiments, the amplification circuit 100 may operate in at least one gain mode to provide different levels of gain. For example, in a first gain mode, the amplification circuit 100 may provide a first gain, while in a second gain mode, the amplification circuit 100 may provide a smaller gain such as a second gain. The second transistor T2 may be turned on or off based on the first bias signal SB1, and the third transistor T3 may be turned on or off based on the first control signal SC1. Specifically, in the first gain mode, the first bias signal SB1 may be set to a high level so as to turn on the second transistor T2. The first control signal SC1 may be set to a low level so as to turn off the third transistor T3. In the first gain mode, a first transmission path for the RF signal may substantially include the first transistor T1 and the second transistor T2. In the second gain mode, the first bias signal SB1 may be set to the low level so as to turn off the second transistor T2. The first control signal SC1 may be set to the high level so as to turn on the third transistor T3. In the second gain mode, a second transmission path for the RF signal may substantially include the first transistor T1 and the third transistor T3. However, the disclosure is not such limited. In a further embodiment, the amplification circuit 100 may operate in a third gain mode, where the second transistor T2 may be turned on based on the first bias signal SB and the third transistor T3 may be turned on based on the first control signal SC1. In such a gain mode, the amplification circuit may provide a third gain greater than the first gain.

In the above embodiments, the resistance of the second transistor T2 when turned on may be referred to as a second ON-resistance Ron2, while the resistance of the third transistor T3 when turned on may be referred to as a third ON-resistance Ron3, with the third ON-resistance Ron3 being less than the second ON-resistance Ron2. For example, in the case where the second transistor T2 and third transistor T3 are fabricated using the same process, the gate width of the third transistor T3 may be greater than that of the second transistor T2, or the number of fingers in the third transistor T3 may be greater than that in the second transistor T2. Alternatively, in the case where different fabrication processes are used, the channel length of the third transistor T3 may be greater than that of the second transistor T2, such that the maximum withstand voltage of the third transistor T3 may be greater than that of the second transistor T2. For example, the maximum withstand voltage of the third transistor T3 may be 2.5V, and the maximum withstand voltage of the second transistor T2 may be 1.2V. However, it should be appreciated that the above is only described for example, and is not intended for limitation.

In some embodiments, in the first gain mode, a first voltage difference may be present between the first terminal and second terminal of the second transistor T2. When switching to the second gain mode, the third transistor T3 may be turned on. Since the ON-resistance Ron3 of the third transistor T3 is less than the ON-resistance Ron2 of the second transistor T2, the turned-on third transistor T3 may reduce the voltage difference between the first terminal and second terminal of the second transistor T2, for example, from the first voltage difference to a smaller second voltage difference. Moreover, the second signal path of the amplifier circuit 100 (for example, including the first transistor T1 and the third transistor T3) may have lower insertion loss, thereby providing better linearity. In other words, the linearity of the second gain mode may be superior to the linearity of the first gain mode.

In some embodiments, when switching mode, the voltage difference between the first and second terminals of the first transistor T1 may vary. For instance, as shown in FIG. 1, when switching mode, the voltage at the first terminal (e.g., source) of the first transistor T1 may substantially not change (e.g., may substantially maintained at the level provided by the reference voltage terminal), while the voltage at the second terminal may vary. Specifically, when switching from the first gain mode to the second gain mode, the voltage at the second terminal of the first transistor T1 may increase due to the lower ON-resistance Ron3 of the third transistor T3 compared to the second transistor T2, so as to enlarge the voltage difference between the first and second terminals of the first transistor T1. In some applications, the enlarged voltage difference may lead to breakdown of the first transistor T1.

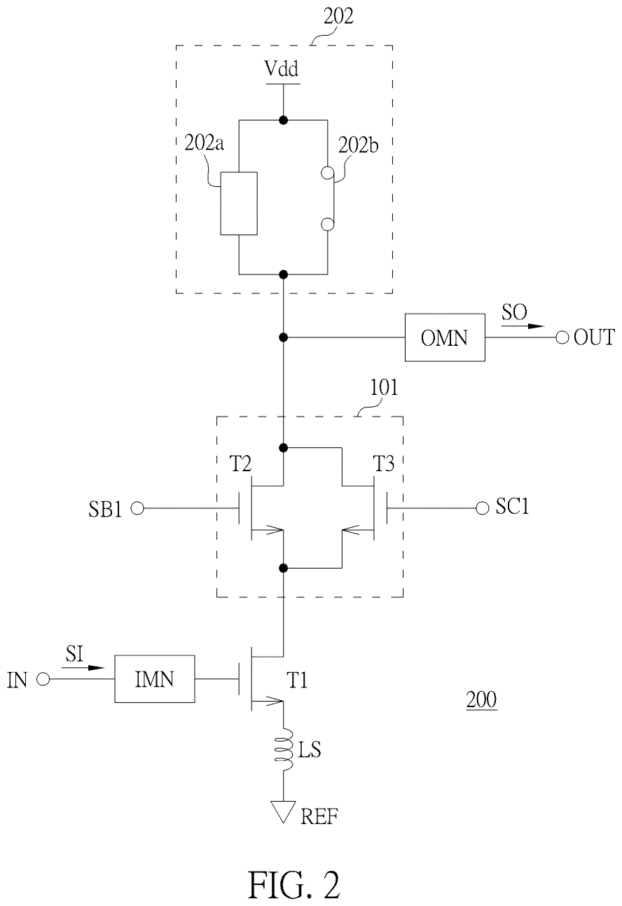

FIG. 2 illustrates a schematic diagram of an amplification circuit 200 according to an embodiment of the present invention. The amplification circuit 200 shown in FIG. 2 is similar to the amplification circuit 100 depicted in FIG. 1, and future details may not be repeated. Some difference may be described below.

In FIG. 2, the voltage adjustment circuit 202, for example, may be an embodiment of the voltage adjustment circuit 102 in FIG. 1. The voltage adjustment circuit 202 may include an operation voltage terminal Vdd, a voltage divider element 202a, and a switch 202b. The operation voltage terminal Vdd may supply an operation voltage of approximately 1.8V, 2.7V, or 5V. One end of the voltage divider element 202a may be coupled to the second terminal (e.g., drain) of the second transistor T2 in the variable impedance element 101, while the other end may be coupled to the operation voltage terminal Vdd. The switch 202b may be coupled in parallel with the voltage divider element 202a.

In some embodiments, the voltage adjustment circuit 202 may be used to adjust the voltage at the drain (e.g., the second terminal) of the second transistor T2. In the first gain mode, the switch 202b may be turned on, such that a current may flow through the switch 202b and substantially bypass the voltage divider element 202a. In the second gain mode, the switch 202b may be turned off, such that a current may flow through the voltage divider element 202a and substantially bypass the switch 202b. In the second gain mode, the presence of the voltage divider element 202a may result in a lower voltage at the second terminal of the second transistor T2 compared to the first gain mode. This may, in turn, reduce the voltage at the second terminal of the first transistor T1. Additionally, the voltage at the first terminal of the first transistor T1 may depend on the voltage level at the reference voltage terminal REF and may substantially not change. As a result, the voltage difference between the first and second terminals of the first transistor T1 may be prevented from exceeding the breakdown voltage, thereby reducing the likelihood of a breakdown in the first transistor T1.

While the above embodiment illustrates the application of the voltage adjustment

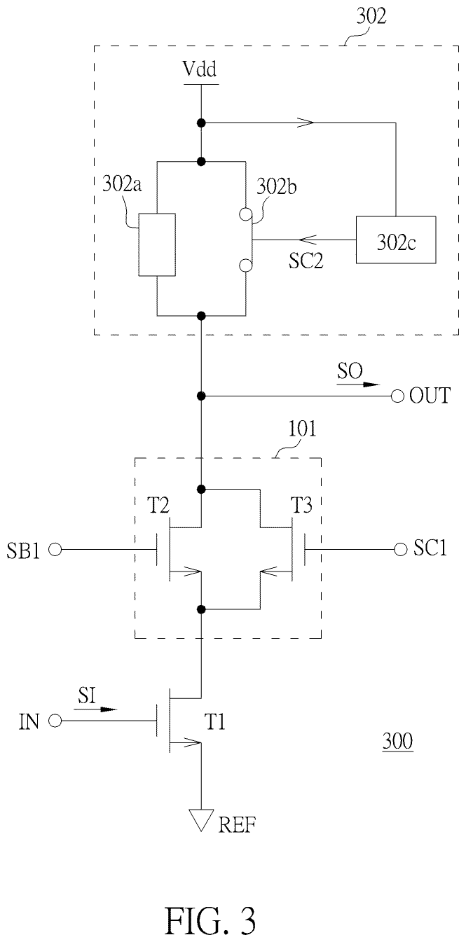

circuit 202, the invention is not such limited. In other embodiments, the switching of the switch 202b in the voltage adjustment circuit 202 may not necessarily correspond to the switching of the gain modes of the amplification circuit. This will be further explained below with reference to FIG. 3. In some embodiments, the voltage divider element 202a may include a resistor, a diode, or other suitable components, and the invention imposes no limitations in this regard.

Furthermore, as shown in FIG. 2, the amplification circuit 200 may further

include an input matching network IMN and an output matching network OMN which may be configured to adjust the input impedance and/or output impedance, respectively, of the amplification circuit 200, so as to improve power transmission efficiency. The input matching network IMN may be at least partially coupled between the signal input terminal IN and the control terminal of the first transistor T1. The output matching network OMN may be at least partially coupled between the second terminal of the second transistor T2 and the signal output terminal OUT. For example, the output matching network OMN may include a variable inductor and a variable capacitor. In some embodiments, the amplification circuit 200 may further include an inductor LS coupled between the first terminal of the first transistor T1 and the reference voltage terminal REF.

FIG. 3 illustrates a schematic diagram of an amplification circuit 300 according to an embodiment of the present invention. The amplification circuit 300 shown in FIG. 3 is similar to the amplification circuit 200 depicted in FIG. 2, future details may not be repeated, and some difference may be described below.

The voltage adjustment circuit 302 in FIG. 3 further includes a detection circuit 302c which may be coupled to the operation voltage terminal Vdd and coupled to the switch 302b. The detection circuit 302c may be configured to provide a second control signal SC2 to the switch 302b based on the level of the operation voltage. The second control signal SC2 may be used to control the operating state of the switch 302b, such as an ON state or an OFF state. For example, when the operation voltage is at a lower first level, the switch 302b may be turned on, and when a higher second level, the switch 302b may be turned off. As for the latter, since the current flows through the voltage divider element 302a, the voltage at the second terminal of the second transistor T2 may be reduced. Consequently, the voltage at the second terminal of the first transistor T1 may also be lowered, reducing the likelihood of a breakdown in the second transistor T2 and/or the first transistor T1. Thus, the amplification circuit 300 is suitable for applications involving various operation voltages.

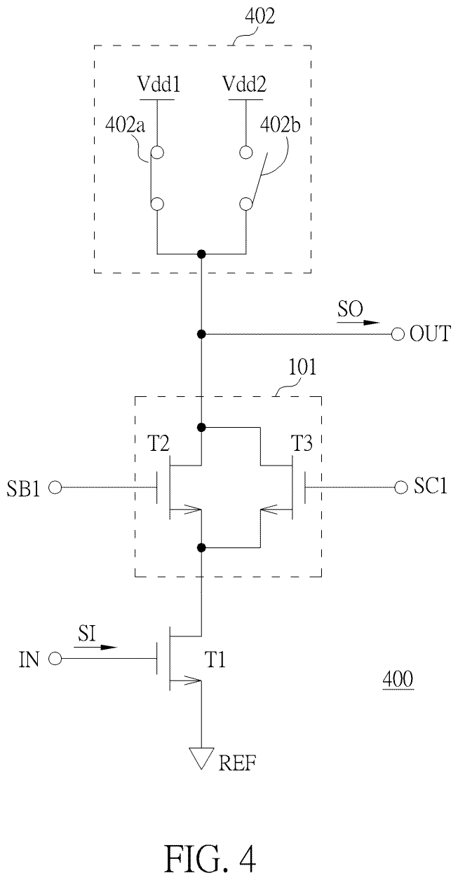

FIG. 4 illustrates a schematic diagram of an amplification circuit 400 according to an embodiment of the present invention. The amplification circuit 400 in FIG. 4 is similar to the amplification circuit 100 in FIG. 1, future details may not be repeated, and some difference may be described below.

The voltage adjustment circuit 402 in FIG. 4 may include a first operation voltage terminal Vdd1, a first switch 402a, a second operation voltage terminal Vdd2, and a second switch 402b. The first operation voltage terminal Vdd1 may receive a first operation voltage. The first switch 402a may be coupled between the first operation voltage terminal Vdd1 and the second terminal of the second transistor T2. The second operation voltage terminal Vdd2 may receive a second operation voltage different from the first operation voltage. For example, the first operation voltage may be greater than the second operation voltage. The second switch 402b may be coupled between the second operation voltage terminal Vdd2 and the second terminal of the second transistor T2.

In some embodiments, the voltage adjustment circuit 402 may be configured to adjust the voltage at the second terminal of the second transistor T2. Specifically, in the first gain mode, the first switch 402a may be turned on, and the second switch 402b may be turned off, thereby providing a higher voltage at the second terminal of the second transistor T2. In the second gain mode, the first switch 402a may be turned off, and the second switch 402b may be turned on, thereby providing a lower voltage at the second terminal of the second transistor T2.

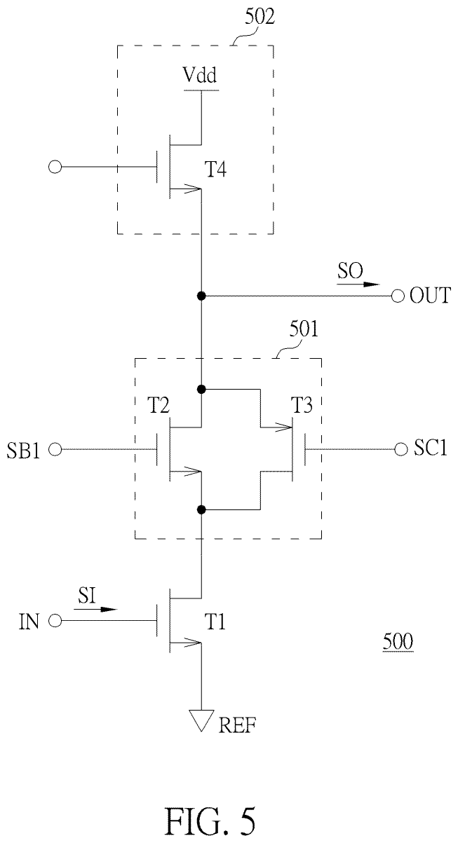

FIG. 5 illustrates a schematic diagram of an amplification circuit 500 according to an embodiment of the present invention. The amplification circuit 500 in FIG. 5 is similar to the amplification circuit 100 in FIG. 1, future details may not be repeated, and some difference may be described below.

The variable impedance element 501 includes a second transistor T2 and a third transistor T3, where the second transistor T2 may be implemented as an N-type transistor, and the third transistor T3 may be implemented as a P-type transistor. For example, a P-type transistor may provide a lower ON-resistance. Additionally, the voltage adjustment circuit 502 may include an operation voltage terminal Vdd and a fourth transistor T4. The operation voltage terminal Vdd may receive an operation voltage. The first terminal of the fourth transistor T4 may be coupled to the second terminal of the second transistor T2, and the second terminal may be coupled to the operation voltage terminal Vdd. The control terminal of the fourth transistor T4 may receive a control signal to adjust the ON-resistance of the fourth transistor T4, that is, the forth ON-resistance Ron4. For example, the fourth transistor T4 may change its ON-resistance Ron4 based on the control signal, thereby changing the voltage level at the second terminal of the second transistor T2.

In at least one of the embodiments above, the amplification circuit may provide improved linearity in various gain modes. Furthermore, with the voltage adjustment circuit, the likelihood of transistor breakdown within the amplification circuit may be reduced, thereby enhancing the circuit's reliability. Additionally, by configuring the body terminal of a transistor as floating or contact-connected, an improved balance between the noise figure and transient response of the amplification circuit may be achieved. These advantages are provided to facilitate understanding of the invention. It is noted that the advantage(s) is not required to accompany with every embodiment.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplification circuit comprising:
a signal input terminal configured to receive a radio frequency (RF) signal;
a signal output terminal configured to output an amplified RF signal;
a first transistor having a first terminal coupled to a reference voltage terminal and a control terminal coupled to the signal input terminal;
a variable impedance element coupled between the first transistor and the signal output terminal, the variable impedance element including a second transistor, wherein a first terminal of the second transistor is coupled to a second terminal of the first transistor, a second terminal of the second transistor is coupled to the signal output terminal, and a control terminal of the second transistor is configured to receive a first bias signal; and
a voltage adjustment circuit coupled to the variable impedance element and configured to adjust a voltage at the second terminal of the second transistor.

2. The amplification circuit of claim 1, wherein the variable impedance element further comprises:
a third transistor, wherein a first terminal of the third transistor is coupled to the first terminal of the second transistor, a second terminal of the third transistor is coupled to the second terminal of the second transistor, and a control terminal of the third transistor is configured to receive a first control signal.

3. The amplification circuit of claim 2, wherein the second transistor has a second ON-resistance, the third transistor has a third ON-resistance, and the third ON-resistance is less than the second ON-resistance.

4. The amplification circuit of claim 2, wherein:
the first transistor further comprises a body terminal that is floating;
the second transistor further comprises a body terminal that is floating; and
the third transistor further comprises a body terminal that is contact-connected.

5. The amplification circuit of claim 2, wherein the amplification circuit operates in at least one gain mode, wherein:
in a first gain mode, the amplification circuit provides a first gain;
in a second gain mode, the amplification circuit provides a second gain; and
the first gain is greater than the second gain.

6. The amplification circuit of claim 5, wherein:
in the first gain mode, the second transistor is turned on based on the first bias signal, and the third transistor is turned off based on the first control signal, wherein a first signal path includes the first transistor and the second transistor; and
in the second gain mode, the second transistor is turned off based on the first bias signal, and the third transistor is turned on based on the first control signal, wherein a second signal path includes the first transistor and the third transistor.

7. The amplification circuit of claim 6, wherein:
in the first gain mode, a first voltage difference exists between the first terminal and the second terminal of the second transistor;
in the second gain mode, a second voltage difference exists between the first terminal and the second terminal of the second transistor; and
the second voltage difference is less than the first voltage difference.

8. The amplification circuit of claim 5, wherein:
in the first gain mode, the amplification circuit provides a first linearity;
in the second gain mode, the amplification circuit provides a second linearity; and
the second linearity is better than the first linearity.

9. The amplification circuit of claim 5, wherein:
in a third gain mode, the second transistor is turned on based on the first bias signal and the third transistor is turned on based on the first control signal for the amplification circuit to provide a third gain, and the third gain is greater than the first gain.

10. The amplification circuit of claim 1, wherein the voltage adjustment circuit comprises:
an operation voltage terminal configured to provide an operation voltage;
a voltage divider element comprising a first terminal coupled to the second terminal of the second transistor and a second terminal coupled to the operation voltage terminal; and
a switch connected in parallel with the voltage divider element.

11. The amplification circuit of claim 10, wherein:
in the first gain mode, the switch is turned on; and
in the second gain mode, the switch is turned off.

12. The amplification circuit of claim 10, wherein the voltage divider element comprises a resistor or a diode.

13. The amplification circuit of claim 10, wherein the voltage adjustment circuit further comprises:
a detection circuit coupled to the operation voltage terminal and the switch, wherein the detection circuit provides a second control signal based on the level of the operation voltage, and the switch is turned on or off based on the second control signal.

14. The amplification circuit of claim 13, wherein:
when the operation voltage is at a first level, the switch is turned on; and
when the operation voltage is at a second level higher than the first level, the switch is turned off.

15. The amplification circuit of claim 1, wherein the voltage adjustment circuit comprises:
a first operation voltage terminal configured to receive a first operation voltage;
a first switch coupled between the first operation voltage terminal and the second terminal of the second transistor;
a second operation voltage terminal configured to receive a second operation voltage, wherein the first operation voltage is greater than the second operation voltage; and
a second switch coupled between the second operation voltage terminal and the second terminal of the second transistor.

16. The amplification circuit of claim 15, wherein:
in the first gain mode, the first switch is turned on and the second switch is turned off; and
in the second gain mode, the first switch is turned off and the second switch is turned on.

17. The amplification circuit of claim 1, wherein the voltage adjustment circuit comprises:
an operation voltage terminal configured to receive an operation voltage; and
a fourth transistor, wherein the first terminal of the fourth transistor is coupled to the second terminal of the second transistor, the second terminal of the fourth transistor is coupled to the operation voltage terminal, and the control terminal of the fourth transistor is configured to receive a control signal for adjusting a fourth ON-resistance of the fourth transistor.

18. The amplification circuit of claim 2, wherein the second transistor comprises an N-type transistor and the third transistor comprises a P-type transistor.

19. The amplification circuit of claim 1, wherein:
the control terminal of the first transistor is configured to receive the first bias signal or a second bias signal different from the first bias signal.

20. The amplification circuit of claim 1, further comprising:
an input matching network at least partially coupled between the signal input terminal and the control terminal of the first transistor; and
an output matching network at least partially coupled between the second terminal of the second transistor and the signal output terminal.
